(19) United States
(12) Patent Application Publication
(10) Pub. No.: US 2025/0248130 A1
(43) Pub. Date: Jul. 31, 2025

(54) ELECTROSTATIC DISCHARGE CLAMP CIRCUIT CONTAINING A DISABLE CIRCUIT TO SELECTIVELY DISABLE A DISCHARGE CIRCUIT

(71) Applicant: Microchip Technology Incorporated, Chandler, AZ (US)

(72) Inventors: Zbigniew Lata, Austin, TX (US); Lunal Khuon, West Chester, PA (US)

(73) Assignee: Microchip Technology Incorporated, Chandler, AZ (US)

(21) Appl. No.: 18/642,020

(22) Filed: Apr. 22, 2024

Related U.S. Application Data
(60) Provisional application No. 63/627,188, filed on Jan. 31, 2024.

(51) Int. Cl. H01L 27/02; H02H 9/04

(52) U.S. Cl. CPC H10D 89/819; H02H 9/046

(57) ABSTRACT

A system and method for an electrostatic discharge (ESD) clamp circuit containing a disable circuit to selectively disable a discharge circuit is disclosed. An electrostatic discharge (ESD) clamp circuit including a discharge circuit to discharge a current flow during a transient ESD voltage event; a disable input to receive a disable input signal; and a disable circuit to, based upon the disable input signal, selectively disable the discharge circuit. When the disable input signal is a first logic state, the disable circuit is to allow the discharge circuit to be enabled; and when the disable input signal is in a second logic state, the disable circuit is to disable the discharge circuit.

### PRIORITY

This application claims priority to U.S. Provisional Patent Application No. 63/627,188, filed Jan. 31, 2024, the contents of which are hereby incorporated in their entirety.

### TECHNICAL FIELD

The present disclosure relates to protection of semiconductor integrated circuits from electrostatic discharge (ESD) with active clamps, and more particularly to protection of active ESD clamps from transient powered electrical overstress (EOS) voltage events.

### BACKGROUND

Modern electronic equipment use semiconductor integrated circuits (ICs) for operation. The semiconductor ICs receive inputs from various sources, e.g., pushbuttons or sensors, without limitation, and have outputs that control operation of the equipment based upon the various inputs. The inputs and outputs of the semiconductor ICs may be subject to undesirable high voltage electrostatic discharge (ESD) in addition to the desired input or output signal level. The ESD, characterized by fast transient high voltage discharges, may be from static electricity generated by a user of the equipment, equipment handling, and the like. An ESD event may create a sufficiently high voltage to cause destructive breakdown of transistor devices connected to the inputs and/or outputs of the semiconductor integrated circuits.

To protect ICs from ESD, the IC may include ESD clamp circuits. The ESD clamp circuit may be static or active. A static ESD clamp circuit is activated when an input voltage is above a certain level. An active ESD clamp circuit is activated when the circuit detects a rapid change in voltage. Active ESD clamp circuits are normally used and placed at the input supply voltage pin (e.g., V_{DD}, V_{CC}) within the pad ring of the IC to prevent damage to sensitive circuits at the core of the IC. In such cases, the active ESD clamp is commonly referred to as a rail clamp. The ESD clamp circuit does not operate unless there is an ESD event. During an ESD event, the active ESD clamp circuit is turned on and provides a pathway between the input to ground for the ESD-induced current to flow so that the current is diverted away from the protected circuits in the IC, preventing damage to those circuits. Although ESD-induced currents may be large, the ESD event is typically short and the active ESD clamp circuit turns off after the event and is not part of the normal operation of the IC.

In some circumstances during operation of the IC, an event may produce transient powered electrical overstress (EOS) voltages that eventually cause catastrophic damage to the active ESD clamp circuit, leaving the IC vulnerable to subsequent ESD events or rendering the entire chip that contains the IC inoperable. For example, a transient powered EOS voltage may occur when the ports of the chip are inadvertently short-circuited together or when the IC experiences a large voltage ripple. Thus, there is a need for an enhanced active ESD clamp circuit that can withstand a transient powered EOS voltage event.

### SUMMARY OF THE INVENTION

Aspects provide systems and methods for an electrostatic discharge (ESD) clamp circuit containing a disable circuit to selectively disable a discharge circuit. An electrostatic discharge (ESD) clamp circuit including a discharge circuit to discharge a current flow during a transient ESD voltage event; a disable input to receive a disable input signal; and a disable circuit to, based upon the disable input signal, selectively disable the discharge circuit. When the disable input signal is a first logic state, the disable circuit is to allow the discharge circuit to be enabled; and when the disable input signal is in a second logic state, the disable circuit is to disable the discharge circuit.

An apparatus includes an input voltage pin; a ground pin; a discharge circuit coupled between the input voltage pin and the ground pin, the discharge circuit to discharge a current flow during a transient ESD voltage event, wherein the discharge circuit includes a first switch; a disable input to receive a disable input signal; and a disable circuit coupled between the discharge circuit and the disable input to disable the discharge circuit, wherein the disable circuit includes a second switch. When the disable input signal is a first logic state, the disable circuit is to allow the discharge circuit to be enabled; and when the disable input signal is in a second logic state, the disable circuit is to disable the discharge circuit.

A method includes receiving a disable input signal; enabling a discharge circuit coupled between an input supply voltage pin and a ground pin of an integrated circuit to provide a low resistance electrical path between the input supply voltage pin and the ground pin for a transient electrostatic discharge (ESD) voltage event when the disable input signal is at a first logic state; and disabling the discharge circuit so as not to provide the low resistance electrical path between the input supply voltage pin and the ground pin for a transient powered electrical overstress (EOS) voltage event when the disable input signal is at a second logic state.

### BRIEF DESCRIPTION OF THE DRAWINGS

The figures illustrate examples of systems and methods.

FIG. 1 is an illustration of an active electrostatic discharge (ESD) clamp circuit to protect a discharge circuit of the ESD clamp circuit from transient powered electrical overstress (EOS) voltage events, according to examples of the present disclosure;

FIG. 2 is a more detailed illustration of an active ESD clamp circuit shown in FIG. 1, according to examples of the present disclosure;

FIG. 3 illustrates a method of operating an active ESD clamp circuit, according to examples of the present disclosure; and

FIG. 4 illustrates a more detailed version of the method of FIG. 3, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, an active electrostatic discharge (ESD) clamp circuit is provided. The active ESD clamp circuit includes a disable input and associated circuitry, hereinafter referred to as a “disable circuit,” added to a conventional active ESD clamp, hereinafter referred to as a “discharge circuit,” to selectively disable the discharge circuit to protect the discharge circuit from transient powered electrical overstress (EOS) voltage events having a longer duration than an ESD event (e.g., inadvertent short circuit, large voltage ripple, large, long duration transient voltage event, or transient powered EOS voltage event). The disable circuit prevents damage to the components of the discharge circuit with no or minimal degradation in the performance of the discharge circuit during an ESD event while the integrated circuit (IC) of which the active ESD clamp is a part is powered off.

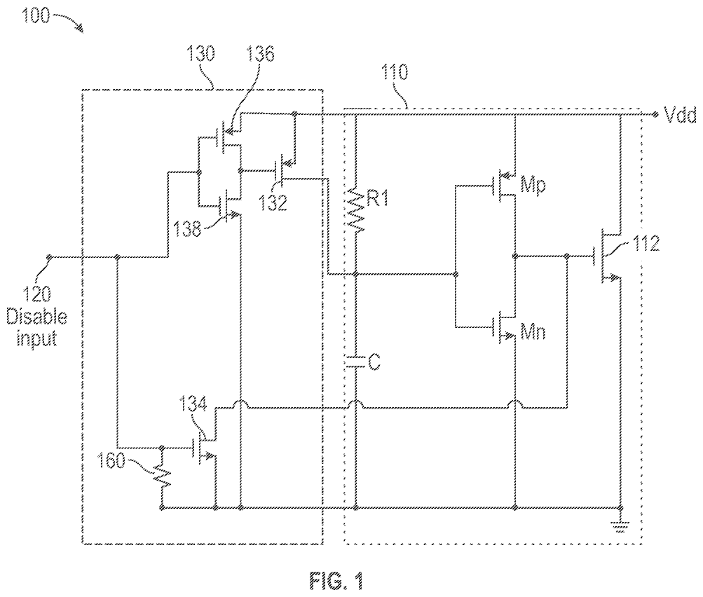

FIG. 1 is an illustration of an active ESD clamp circuit to protect a discharge circuit of the ESD claim circuit from transient powered EOS voltage events, according to examples of the present disclosure. Active ESD clamp circuit 100 includes discharge circuit 110 between the input voltage (V_{DD}) and ground (GND). Discharge circuit 110 may provide a pathway between the input voltage and ground for ESD-induced current to flow so that the current is diverted away from the protected circuits in the integrated circuit (IC) of which active ESD clamp circuit 100 is a part. Discharge circuit 110 may include an ESD detection circuit formed of resistor R1 and capacitor C. Discharge circuit 110 may additionally include switches Mₚ, Mₙ, and switch 112. During an ESD event, switch Mₚ may close to allow the current from the ESD event to be discharged via switch 112, shown without limitation as an n-type metal-oxide-semiconductor field-effect transistor (NMOSFET).

A first end of resistor R1 is connected to V_{DD}, and a second end of resistor R1 is connected to a first end of capacitor C and to the gates of switches Mₚ and Mₙ. Switch Mₚ is shown without limitation as a p-type metal-oxide semiconductor field-effect transistor (PMOSFET) and switch Mₙ is shown without limitation as an NMOSFET. The source of switch Mₚ is connected to V_{DD} and the drain of switch Mₚ is connected to the drain of switch Mₙ and to the gate of switch 112. The source of switch Mₙ is connected to ground. The term ground, as used herein is meant to be a common voltage, and is not limited to earth ground.

In operation in the event of an ESD transient event, the voltage at the gates of switches is constrained from rising to the full voltage of the transient on V_{DD} by the action of capacitor C, and as a result switch Mₚ is turned on, turning on switch 112. Once capacitor C is charged to VDD, switch Mₚ turns off and switch Mₙ turns on, thereby opening switch 112.

Active ESD clamp circuit 100 also includes disable input 120 and disable circuit 130. Disable circuit 130 may be coupled between discharge circuit 110 and disable input 120 and may include switches 132, 134, 136, and 138. Switches 112, 132, 134, 136, and 138 may be transistors, such as a bipolar junction transistor (BJT), p-channel metal-oxide-semiconductor transistor (PMOS), N-type metal-oxide-semiconductor transistor (NMOS), complementary metal-oxide-semiconductor transistor (CMOS), MOSFET, any general device that may perform the function of an electronic switch, or any combination thereof. While FIG. 1 illustrates disable circuit 130 as having four switches 132, 134, 136, and 138, in some examples, disable circuit 130 may have any suitable number of switches such that disable circuit 130 may disable switch 112 of discharge circuit 110.

Disable input 120 may receive a disable input signal. The disable input signal may be a logical signal with either a first logic state (e.g., value of 0) or a second logic state (e.g., value of 1), produced by, among others, a microcontroller or a power-on reset circuit. Disable input signal may be at the first logic state when no power is applied to the IC. During power-up and initialization, disable input signal may remain at the first logic state until the initialization complete signal is received, at which point disable input signal may be at the second logic state. The disable input signal may default to the second logic state after the IC is initialized.

The disable input signal may control the state of one or more switches in disable circuit 130. Specifically, when disable input signal is at the first logic state, switch 134, shown without limitation as an NMOSFET, may be open. When switch 134 is open, disable circuit 130 may not be active and discharge circuit 110 may function as a conventional active ESD clamp circuit and may be activated when a fast rising, short duration ESD event occurs on the V_{DD} pin by diverting the ESD-induced current from V_{DD} to ground. The drain of switch 134 is connected to the gate of switch 112, and as a result, when disable input 120 signal at the second logic state, switch 134 may be closed, pulling the input to switch 112 low, effectively opening switch 112.

Additionally, in examples where disable circuit 130 includes more than one switch, when disable input signal is at the second logic state, switches 136 and 138, shown without limitation as a PMOSFET and an NMOSFET, respectively, may act as an inverter and may produce a low output at the input to switch 132, shown without limitation as a PMOSFET, closing switch 132. When switch 132, whose drain is connected to the gates of switches Mₚ and Mₙ, is closed, switch 132 pulls the input to the inverter consisting of switches Mₚ and Mₙ high, thereby opening switch Mₚ and closing switch Mₙ, which pulls the input to switch 112 low, effectively opening switch 112. Because disable input signal may be at the second logic state during normal operation (after initialization), switch 112 may remain open while the IC is normally operating.

When switch 112 is open, discharge circuit 110 may also be disabled and any non-ESD voltage event (e.g., ringing, voltage ripple) will not flow through discharge circuit 110. Thus, during any voltage event occurring after initialization, discharge circuit 110 may remain off, protecting discharge circuit 110 from damage.

In some examples, disable circuit may further include resistor 160. Resistor 160 may pull switch 134 to ground such that switch 134 remains open while the IC is powered off.

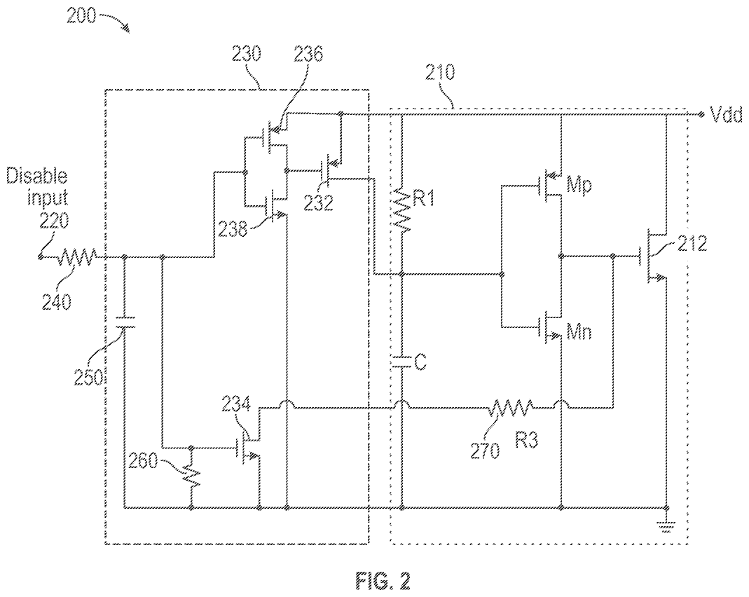

FIG. 2 is a more detailed illustration of an active ESD clamp circuit shown in FIG. 1, according to examples of the present disclosure. Active ESD clamp circuit 200 may be similar to active ESD clamp circuit 100 shown in FIG. 1 and may include discharge circuit 210, disable input 220, and disable circuit 230, similar to discharge circuit 110, disable input 120, and disable circuit 130, respectively shown in FIG. 1.

Discharge circuit 210 may be connected between the input voltage (V_{DD}) and ground (GND) and may provide a pathway between the input voltage and ground for ESD-induced current to flow so that the current is diverted away from the protected circuits in the IC of which active ESD clamp circuit 200 is a part. Discharge circuit 210 may include an ESD detection circuit formed of resistor R1 and capacitor C. Discharge circuit 210 may additionally include switches Mₚ, Mₙ, and switch 212. During an ESD event, switch Mₚ may close to allow the current from the ESD event to be discharged via switch 212. Switch 212 may be similar to switch 112 shown in FIG. 1.

Disable circuit 230 may be coupled between discharge circuit 210 and disable input 220 and may include switches 232, 234, 236, and 238. Switches 232, 234, 236, and 238 may be similar to switches 132, 134, 136, and 138, respectively, shown in FIG. 1. While FIG. 2 illustrates disable circuit 230 as having four switches 232, 234, 236, and 238, in some examples, disable circuit 230 may have any suitable number of switches such that disable circuit 230 may disable switch 212 of discharge circuit 210.

Disable input 220 may receive a disable input signal and may be similar to disable input 120 shown in FIG. 1. The disable input signal may be a logical signal with either a first logic state (e.g., value of 0) or a second logic state (e.g., value of 1), produced by, among others, a microcontroller or a power-on reset circuit. Disable input signal may be at the first logic state when no power is applied to the IC. During power-up and initialization, disable input signal may remain at the first logic state until the initialization complete signal is received, at which point disable input signal may be at the second logic state. The disable input signal may default to the second logic state after the IC is initialized.

The disable input signal may control the state of one or more switches in disable circuit 230. Specifically, when disable input signal is at the first logic state, switch 234, shown without limitation as an NMOSFET, may be open. When switch 234 is open, disable circuit 230 may not be active and discharge circuit 210 may function as a conventional active ESD clamp circuit and may be activated when a fast rising, short duration ESD event occurs on the V_{DD} pin by diverting the ESD-induced current from V_{DD} to ground. The drain of switch 234 is connected to the gate of switch 212, and as a result, when disable input 220 signal at the second logic state, switch 234 may be closed, pulling the input to switch 212 low, effectively opening switch 212.

Additionally, in examples where disable circuit 230 includes more than one switch, when disable input signal is at the second logic state, switches 236 and 238 shown without limitation as a PMOSFET and an NMOSFET, respectively, may act as an inverter and may produce a low output at the input to switch 232, shown without limitation as a PMOSFET, closing switch 232. When switch 232, whose drain is connected to the gates of switches Mₚ and Mₙ, is closed, switch 232 pulls the input to the inverter consisting of switches Mₚ and Mₙ high, thereby opening switch Mₚ and closing switch Mₙ which pulls the input to switch 212 low, effectively opening switch 212. Because disable input signal may be at the second logic state during normal operation (after initialization), switch 212 may remain open while the IC is normally operating.

When switch 212 is open, discharge circuit 210 may also be disabled and any non-ESD voltage event (e.g., ringing, voltage ripple) will not flow through discharge circuit 210. Thus, during any voltage event occurring after initialization, discharge circuit 210 may remain off, protecting discharge circuit 210 from damage.

In some examples, active ESD clamp circuit 200 may further include resistor 240 between disable input 220 and disable circuit 230. Resistor 240 may filter the signal from disable input 220 to make the signal more stable. Disable circuit 230 may also include capacitor 250 to provide additional noise immunity for active ESD clamp circuit 200.

In some examples, disable circuit may further include resistors 260 and 270. Resistor 260 may pull switch 234 to ground such that switch 234 remains open while the IC is powered off. Resistor 270 may be used to protect the drain of switch 234 in the event of a voltage spike due to unknown V_{DD} transients.

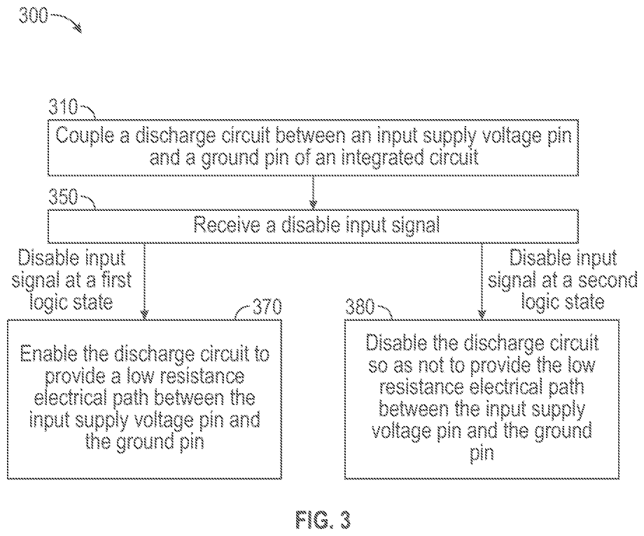

FIG. 3 illustrates a method of operating an active ESD clamp circuit, according to examples of the present disclosure. Method 300 may be implemented using any of the components shown in FIGS. 1-2, such as discharge circuit 110 and 220, disable circuit 130 and 230, and disable input 120 and 220, by themselves or in combination, or any other component operable to implement method 300. Although examples have been described above, other variations and examples may be made from this disclosure without departing from the spirit and scope of these disclosed examples.

Method 300 may begin at block 310 where a discharge circuit may be coupled between an input voltage pin and a ground pin of an integrated circuit. The term pin, as used herein, is not meant to be limited to any particular type of physical structure, and may include, without limitation, gull-wing or J-lead terminals, solder balls, or lands. The discharge circuit may provide a pathway between the input voltage and ground for ESD-induced current to flow so that the current is diverted away from protected circuits in the integrated circuit. The discharge circuit may include an ESD detection circuit formed of a resistor and a capacitor. The discharge circuit may additionally include switches that may close during an ESD event to allow the current from the ESD event to be discharged via the discharge circuit.

At block 350, a disable input signal may be received. The disable input signal may be received from a disable input, such as disable input 120 or 220, shown in FIGS. 1 and 2. When the disable input is at a first logic state, at block 370, the coupled discharge circuit of block 310 may be enabled to provide a low resistance electrical path between the input supply voltage pin and the ground pin. When the disable input is at a second logic state, at block 380, the coupled discharge circuit of block 310 may be disabled so as not to provide the low resistance electrical path between the input supply voltage pin and the ground pin.

Although FIG. 3 discloses a particular number of operations related to method 300, method 300 may be executed with greater or fewer operations than those depicted in FIG. 3. In addition, although FIG. 3 discloses a certain order of operations to be taken with respect to method 300, the operations comprising method 300 may be completed in any suitable order.

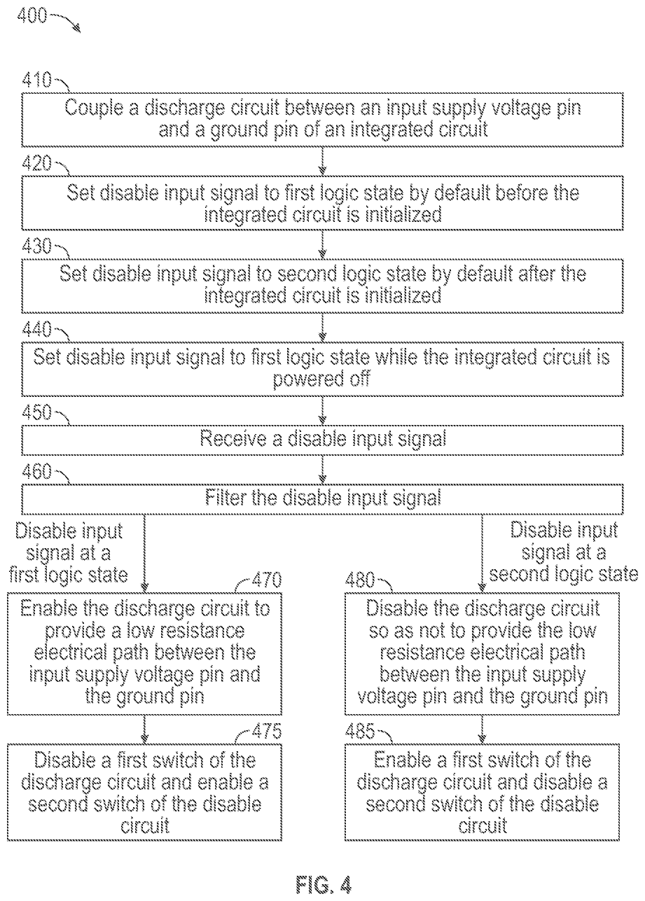

FIG. 4 illustrates a more detailed version of the method of FIG. 3, according to examples of the present disclosure. Method 400 may be implemented using any of the components shown in FIGS. 1-2, such as discharge circuit 110 and 220, disable circuit 130 and 230, and disable input 120 and 220, by themselves or in combination, or any other component operable to implement method 400. Although examples have been described above, other variations and examples may be made from this disclosure without departing from the spirit and scope of these disclosed examples.

Method 400 may begin at block 410 where a discharge circuit may be coupled between an input voltage pin and a ground pin of an integrated circuit. The term pin, as used herein, is not meant to be limited to any particular type of physical structure, and may include, without limitation, gull-wing or J-lead terminals, solder balls, or lands. The discharge circuit may provide a pathway between the input voltage and ground for ESD-induced current to flow so that the current is diverted away from the protected circuits in the integrated circuit. The discharge circuit may include an ESD detection circuit formed of a resistor and a capacitor. The discharge circuit may additionally include switches that may close during an ESD event to allow the current from the ESD event to be discharged via the discharge circuit.

At block 420, a disable input signal may be set to a first logic state by default before the integrated circuit is initialized. As described below with respect to block 470, when the disable input signal is at the first logic state, the discharge circuit may be enabled and may provide a low resistance electrical path between the input supply voltage pin and the ground pin to protect the integrated circuit from an ESD event.

At block 430, the disable input signal may be set to a second logic state by default after the integrated circuit is initialized. As described below with respect to block 480, when the disable input signal is at the second logic state, the discharge circuit may be disabled and may not provide a low resistance electrical path between the input supply voltage pin and the ground pin.

At block 440, the disable input signal may be set to a first logic state while the integrated circuit is powered off. As described below with respect to block 470, when the disable input signal is at the first logic state, the discharge circuit may be enabled and may provide a low resistance electrical path between the input supply voltage pin and the ground pin to protect the integrated circuit from an ESD event.

At block 450, a disable input signal may be received. The disable input signal may be received from a disable input, such as disable input 120 or 220, shown in FIGS. 1 and 2. At block 460, the disable input signal may be filtered. Filtering the disable input signal may make the signal more stable and may prevent overshoots or bouncing.

When the disable input signal is at a first logic state, at block 470, a discharge circuit may be enabled to provide a low resistance electrical path between the input supply voltage pin and the ground pin. At block 475, a first switch of the discharge circuit, such as switch 112 or 212 shown in FIGS. 1 and 2, respectively, may be enabled and a second switch of a disable circuit, such as switches 134 or 234 shown in FIGS. 1 and 2, respectively, may be disabled such that the discharge circuit provides the low resistance electrical path between the input supply voltage pin and the ground pin.

In examples where the disable circuit includes more than one switch, when the disable input signal is at the second logic state, other switches, such as switches 136 and 138 shown in FIG. 1 or switches 236 and 238 shown in FIG. 2, may act as an inverter and may produce a low output at the input to a third switch of the disable circuit, such as switch 132 shown in FIG. 1 or switch 232 shown in FIG. 2, closing the third switch. When the third switch, whose drain is connected to the gates of the switches Mₚ and Mₙ of the discharge circuit, is closed, the third switch pulls the input to the inverter consisting of the switches Mₚ and Mₙ of the discharge circuit high, thereby opening the switch Mₚ and closing the switch Mₙ, which pulls the input to the first switch of the discharge circuit low, effectively opening the first switch of the discharge circuit. Because disable input signal may be at the second logic state during normal operation (after initialization), the first switch of the discharge circuit may remain open while the IC is normally operating.

When the disable input signal is at a second logic state, at block 480, a discharge circuit may be disable so as not to provide a low resistance electrical path between the input supply voltage pin and the ground pin. At block 485, a first switch of the discharge circuit, such as switch 112 or 212 shown in FIGS. 1 and 2, respectively, may be disabled and a second switch of the disable circuit, such as switches 134 or 234 shown in FIGS. 1 and 2, respectively, may be enabled such that there is no low resistance electrical path between the input supply voltage pin and the ground pin via the discharge circuit.

Although FIG. 4 discloses a particular number of operations related to method 400, method 400 may be executed with greater or fewer operations than those depicted in FIG. 4. In addition, although FIG. 4 discloses a certain order of operations to be taken with respect to method 400, the operations comprising method 400 may be completed in any suitable order.

Although examples have been described above, other variations and examples may be made from this disclosure without departing from the spirit and scope of these disclosed examples.

1. An electrostatic discharge (ESD) clamp circuit, comprising:
a discharge circuit to discharge a current flow during a transient ESD voltage event;
a disable input to receive a disable input signal; and
a disable circuit to, based upon the disable input signal, selectively disable the discharge circuit;
wherein:
when the disable input signal is a first logic state, the disable circuit is to allow the discharge circuit to be enabled; and
when the disable input signal is in a second logic state, the disable circuit is to disable the discharge circuit.

2. The electrostatic discharge clamp circuit of claim 1, wherein the disable input signal is at the second logic state by default after an integrated circuit containing the electrostatic discharge clamp circuit is initialized.

3. The electrostatic discharge clamp circuit of claim 1, wherein the disable input signal is at the first logic state while an integrated circuit containing the electrostatic discharge clamp circuit is powered off.

4. The electrostatic discharge clamp circuit of claim 1, comprising:
a filter to stabilize the disable input signal.

5. The electrostatic discharge clamp circuit of claim 1, wherein:
the disable circuit includes a switch; and
the disable input signal controls a state of the switch.

6. The electrostatic discharge clamp circuit of claim 1, wherein the disable input signal is at the first logic state by default before an integrated circuit containing the electrostatic discharge clamp circuit is initialized.

7. The electrostatic discharge clamp circuit of claim 1, wherein the disable circuit is coupled to an input voltage and a ground of an integrated circuit.

8. An apparatus, comprising:
an input voltage pin;
a ground pin;
a discharge circuit coupled between the input voltage pin and the ground pin, the discharge circuit to discharge a current flow during a transient ESD voltage event, wherein the discharge circuit includes a first switch;
a disable input to receive a disable input signal; and
a disable circuit coupled between the discharge circuit and the disable input to disable the discharge circuit, wherein the disable circuit includes a second switch; and
wherein:
when the disable input signal is a first logic state, the disable circuit is to allow the discharge circuit to be enabled; and
when the disable input signal is in a second logic state, the disable circuit is to disable the discharge circuit.

9. The apparatus of claim 8, wherein the disable input signal is at the second logic state by default after an integrated circuit containing the discharge circuit is initialized.

10. The apparatus of claim 8, wherein the disable input signal is at the first logic state while the integrated circuit is powered off.

11. The apparatus of claim 8, comprising:
a filter to stabilize the disable input signal.

12. The apparatus of claim 8, wherein:
the disable input signal controls a state of the second switch.

13. The apparatus of claim 8, wherein the disable input signal is at the first logic state by default before an integrated circuit containing the discharge circuit is initialized.

14. A method, comprising:
receiving a disable input signal;
enabling a discharge circuit coupled between an input supply voltage pin and a ground pin of an integrated circuit to provide a low resistance electrical path between the input supply voltage pin and the ground pin for a transient electrostatic discharge (ESD) voltage event when the disable input signal is at a first logic state; and
disabling the discharge circuit so as not to provide the low resistance electrical path between the input supply voltage pin and the ground pin for a transient powered electrical overstress (EOS) voltage event when the disable input signal is at a second logic state.

15. The method of claim 14, wherein the disable input signal is at the second logic state by default after the integrated circuit is initialized.

16. The method of claim 14, wherein the disable input signal is at the first logic state while the integrated circuit is powered off.

17. The method of claim 14, wherein the disable input signal is at the first logic state by default before the integrated circuit is initialized.

18. The method of claim 14, comprising:
filtering the disable input signal.

19. The method of claim 14, wherein disabling the discharge circuit and enabling the disable circuit when the disable input signal is at the second logic state includes:
disabling a first switch of the discharge circuit; and
enabling a second switch of the disable circuit.

20. The method of claim 14, wherein enabling the discharge circuit and disabling the disable circuit when the disable input signal is at the first logic state includes:
enabling a first switch of the discharge circuit; and
disabling a second switch of the disable circuit.
